(19) United States
(12) Patent Application Publication
(10) Pub. No.: US 2010/0134982 A1
(43) Pub. Date: Jun. 3, 2010

(54) MEMORY HEAT DISSIPATING STRUCTURE AND MEMORY DEVICE HAVING THE SAME

(76) Inventors: George Anthony Meyer, IV, San Jose, CA (US); Chien-Hung Sun, Zhongli City (TW); I-Ying Lee, Zhongli City (TW)

Correspondence Address: HDLS Patent & Trademark Services, P.O. BOX 220746, CHANTILLY, VA, 20153-0746, US

(21) Appl. No.: 12/325,518

(22) Filed: Dec. 1, 2008

(51) Int. Cl. H05K 7/20

(52) U.S. Cl. 361/715; 361/711; 361/717

(57) ABSTRACT

A memory heat dissipating structure clamped on a surface of a memory module includes two heat dissipating plates and two uniform temperature plates. The uniform temperature plate includes first and second surfaces. The first surface of the uniform temperature plate is attached to an internal side of the heat dissipating plate, and the second surface of the uniform temperature plate is attached to the memory module. At least one heat dissipating body is installed on the memory module and clamped between the two heat dissipating plates and the two uniform temperature plates. The heat dissipating body includes a base and heat dissipating fins extended from the base. The base forms a straight section attached onto the second surface of the uniform temperature plate. The two heat dissipating plates are clamped and fixed by fixing elements. The structure of the invention can improve the heat dissipating effect of the memory module.

### BACKGROUND OF THE INVENTION

1. Field of the Invention

The present invention generally relates to a heat dissipating structure, and more particularly to a heat dissipating structure applied in a memory device.

2. Description of Prior Art

As science and technology advance, computer hardware tends to be developed with high speed and high frequency to improve the operating efficiency, and the power consumption also becomes increasingly higher. Compared with the prior art, present electronic devices generate a considerable amount of heat. For instance, a memory module is developed with high speed and high frequency for both clock and bandwidth to cope with the high-speed operations of a processor. The working temperature of the memory module will become increasingly higher, and the heat generated will become higher accordingly. The increasing temperature will definitely affect the performance of the memory module or even damage the memory module. With reference to FIG. 1 for a conventional heat dissipating device used in a random access memory, the heat dissipating device 1 comprises two heat dissipating plates 2 and a plurality of fixing elements 3, wherein the two heat dissipating plates 2 are clamped and attached onto surfaces of the memory module respectively, and a plurality of fixing elements 3 are clamped onto two heat dissipating plates 2, such that the memory module is clamped and fixed by the two heat dissipating plates 2. The two heat dissipating plates 2 are provided for dissipating the high-temperature heat produced after the operation of the memory module. Although the conventional heat dissipating device 1 can dissipate the heat of the memory module, the heat dissipating effect by the two heat dissipating plates 2 is low. Therefore, some manufacturers install a fan on the memory module to solve the problem, but the installed fan comes with a large volume and requires a power source. Obviously, such arrangement does not fit the application in a computer with limited internal space.

In view of the foregoing shortcomings of the prior art, the inventor of the present invention based on years of experience in the related field to conduct extensive researches and experiments, and finally developed a feasible design to overcome the shortcomings of the prior art.

### SUMMARY OF THE INVENTION

It is a primary objective of the present invention to provide a memory heat dissipating structure capable of improving the heat dissipating effect of a memory module and enhancing the practical application of the present invention.

To achieve the foregoing objective, the present invention provides a memory heat dissipating structure clamped and fixed onto a corresponding surface of a memory module, and the heat dissipating structure comprises two heat dissipating plates; at least one uniform temperature plate, having a first surface and a second surface corresponding with each other, wherein the first surface is attached onto an internal side of the heat dissipating plate, and the second surface is attached onto the memory module; at least one heat dissipating body, installed on the memory module and clamped between the two heat dissipating plates, and including a base and a plurality of heat dissipating fins extended from the base, wherein the base forms a straight section attached onto the second surface of the uniform temperature plate; and at least one fixing element, clamped and fixed to the two heat dissipating plates.

It is another objective of the present invention to provide a memory with a heat dissipating structure, wherein a uniform temperature plate and a heat dissipating body are used for quickly removing the heat generated by the memory module, and the thin and light uniform temperature plate fits the application in a computer with limited internal space to improve the practical application of the present invention.

To achieve the foregoing objective, the present invention provides a memory device having a heat dissipating structure, and such device comprises: a memory module; two heat dissipating plates; at least one uniform temperature plate, having a first surface attached with an internal side of the heat dissipating plate and a second surface attached with the memory module; at least one heat dissipating body, installed on the memory module and clamped between the two heat dissipating plates, and having a base and a plurality of heat dissipating fins extended from the base, wherein the base forms a straight section attached onto the second surface of the uniform temperature plate; and at least one fixing element, for clamping and fixing the two heat dissipating plates.

A further objective of the present invention is to provide a memory having a heat dissipating structure, such that the heat dissipating body can be interchangeably inserted onto the heat dissipating plate to enhance the convenience and the practicability of the invention.

### BRIEF DESCRIPTION OF DRAWINGS

FIG. 1 is an exploded view of a conventional heat dissipating device;

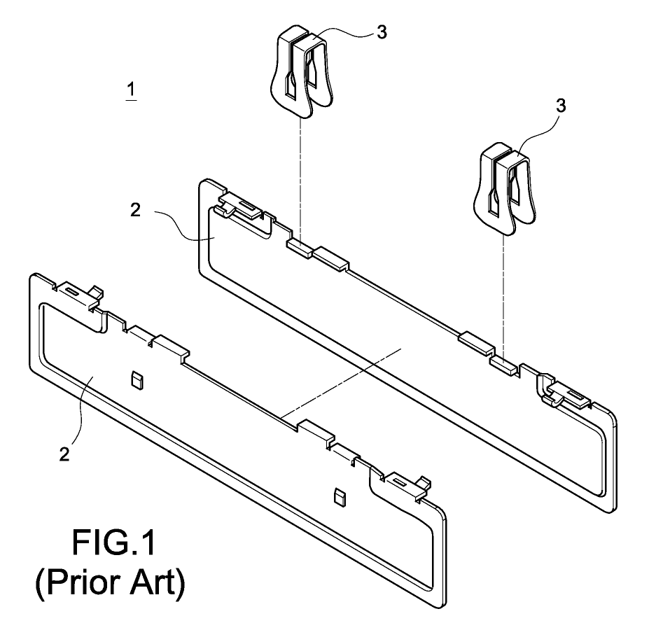

FIG. 2 is a perspective view of a memory heat dissipating structure of the present invention;

FIG. 3 is an exploded view of a memory with a heat dissipating structure of the present invention;

FIG. 4 is a perspective view of a memory with a heat dissipating structure of the present invention;

FIG. 5 is a schematic view of an application of the present invention;

FIG. 6 is a perspective view of a second preferred embodiment of the present invention;

FIG. 7 is a perspective view of a third preferred embodiment of the present invention; and

FIG. 8 is a perspective view of a fourth preferred embodiment of the present invention.

### DETAILED DESCRIPTION OF THE INVENTION

The technical characteristics, features and advantages of the present invention will become apparent in the following detailed description of preferred embodiments with reference to the accompanying drawings, and the preferred embodiments are used for illustrating the present invention only, but not intended to limit the scope of the invention.

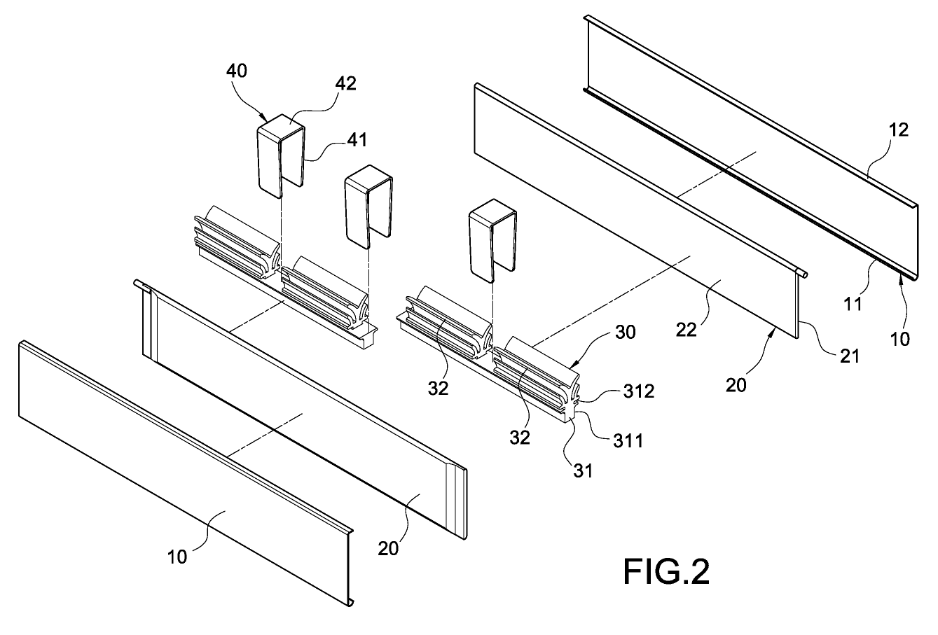

With reference to FIG. 2 for an exploded view of a memory heat dissipating structure in accordance with the present invention, a memory heat dissipating structure comprises two heat dissipating plates 10 and at least one uniform temperature plate 20, and the uniform temperature plate 20 includes a first surface 21 and a second surface 22 corresponding to each other, and a first bent section 11 is inwardly formed from a side of the heat dissipating plate 10, and the first bent section 11 is provided for installing the uniform temperature plate 20, such that the first surface 21 of the uniform temperature plate 20 is attached onto an internal side of the heat dissipating plate 10, wherein each first surface 21 of the two uniform temperature plates 20 is attached onto each respective internal side of the two heat dissipating plates 10; and at least one heat dissipating body 30, including a base 31 and a plurality of heat dissipating fins 32 extended from the base, wherein the base 31 forms a straight section 311 separately on both left and right sides of the base 31 in this preferred embodiment, and one of the sides of the straight section 311 is attached on the second surface 22 of the uniform temperature plate 20, and a second bent section 12 inwardly bent from another side of the heat dissipating plate 10, and the base 31 of the heat dissipating body 30 forms an insert slot 312 for inserting the second bent section 12. In addition, at least one fixing element 40 is installed on the heat dissipating body 30 for lamping and fixing the two heat dissipating plates 10, and the fixing element 40 has a U-shaped cross-section. In other words, the fixing element 40 includes two corresponding elastic clamping plates 41 and a connecting plate 42 coupled to the two clamping plates.

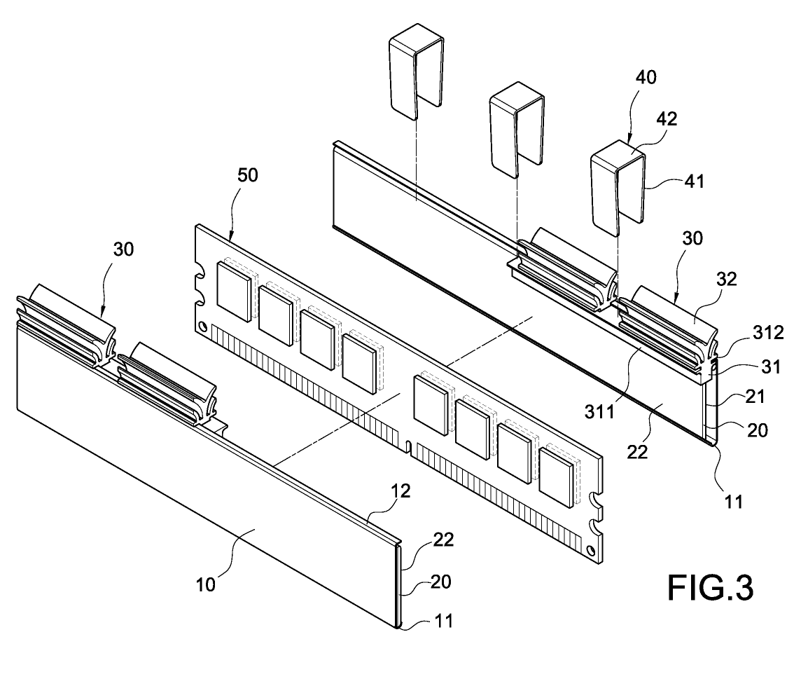

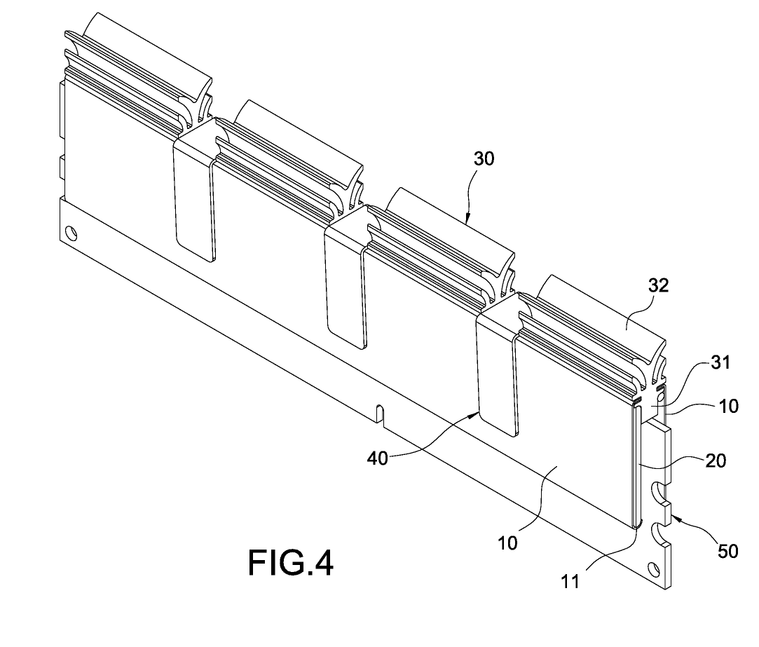

With reference to FIGS. 3 and 4 for a schematic view and a perspective view of a memory heat dissipating structure combined with a memory module in accordance with the present invention, the memory heat dissipating structure is provided for clamping a corresponding surface of a memory module 50, and the uniform temperature plate 20 is contained in the first bent section 11 of the heat dissipating plate 10, such that the first surface 21 of the uniform temperature plate 20 is attached onto an internal side of the heat dissipating plate 10, and the second surface 22 of the uniform temperature plate 20 is attached to the memory module 50; the second bent section 12 of the heat dissipating plate 10 is inserted into the insert slot 312 of the base 31, and the straight section 311 at a side of the base 31 is attached to the uniform temperature plate 20, and another side is attached to the memory module 50, such that the two heat dissipating plates 10 and the two uniform temperature plates 20 are attached onto a corresponding surface of the memory module 50. In addition, a heat dissipating body 30 is clamped between the two heat dissipating plates 10 and the two uniform temperature plates 20, and a plurality of fixing elements 40 are provided for clamping and fixing the two heat dissipating plates 10 on both sides of the memory module 50.

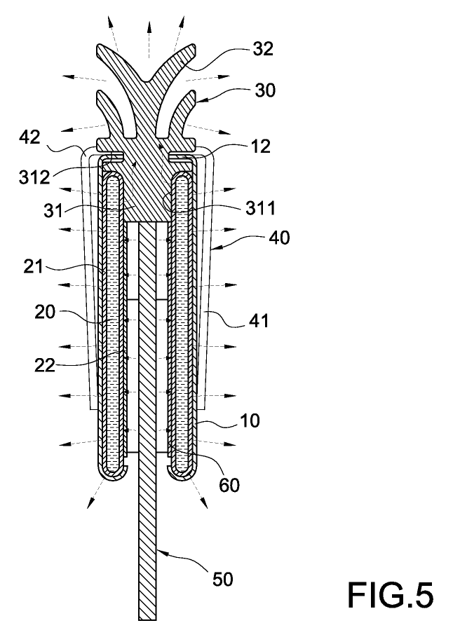

With reference to FIG. 5 for a schematic view of an application of a memory having a heat dissipating structure in accordance with the present invention, a thermal conducting medium 60 is coated between the second surface 22 of the uniform temperature plate 20 and the memory module 50, and the thermal conducting medium 60 can expedite dissipating the heat produced during the operation of the memory module 50 to the uniform temperature plate 20, such that the uniform temperature plate 20 can transmit the heat to the heat dissipating plate 10 quickly. Since a portion of the uniform temperature plate 20 is attached directly with the straight section 311 of the heat dissipating body 30, therefore the heat produced by a portion of the memory module 50 can be transmitted directly to the heat dissipating body 30, and then to the outside quickly through the heat dissipating fin 32 having a large heat dissipating area.

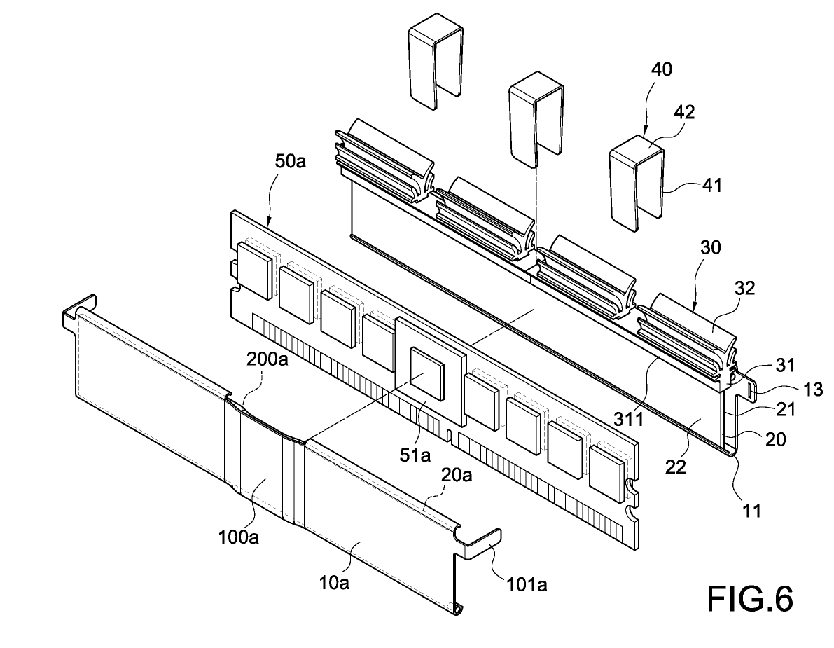

With reference to FIG. 6 for a second preferred embodiment of the present invention, this preferred embodiment is substantially the same as the first preferred embodiment, and the difference resides on the memory module 50a whose central section has a chip 51a disposed at a side of the memory module 50a, and the side also includes a heat dissipating plate 10a and a uniform temperature plate 20a, so that the heat dissipating plate 10 of a uniform temperature plate 20a forms a heat dissipating plate protrusion 100a and a uniform temperature plate protrusion 200a at positions correspond to the chip 51a, and another side of the memory module 50a is combined to a heat dissipating plate 10 and a uniform temperature plate 20, wherein a latch 101a is disposed at an end of the heat dissipating plate 10a, and the heat dissipating plate 10 forms a latch hole 13 corresponding to the latch 101a, and the two heat dissipating plates 10a, 10 are latched with each other by a hook 111a and a latch hole 13 to cover the memory module 50a.

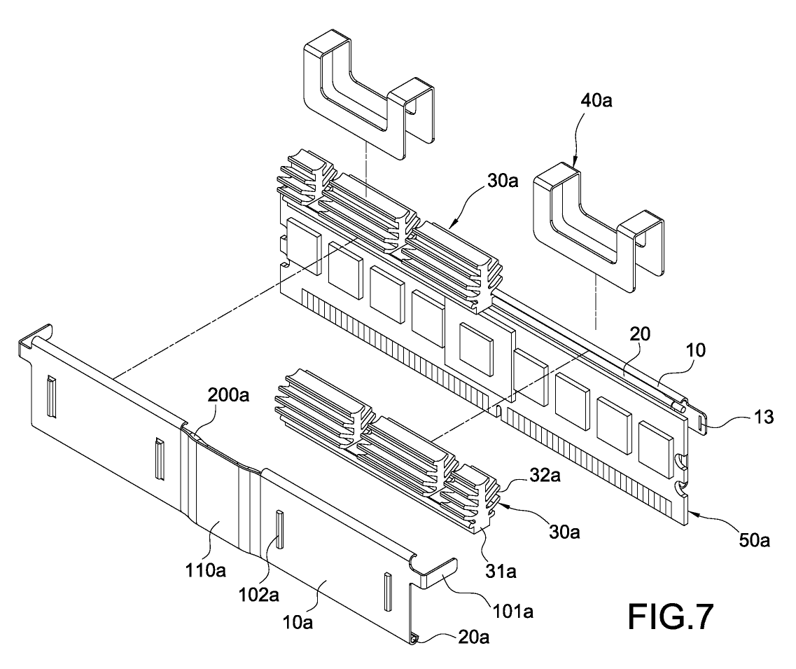

With reference to FIG. 7 for a third preferred embodiment of the present invention, this preferred embodiment is substantially the same as the second preferred embodiment, and the difference resides on the heat dissipating body 30a and the fixing element 40a, and the heat dissipating body 30a includes a base 31a and a heat dissipating fin 32a formed on the base 31a. In this preferred embodiment, the heat dissipating fin 32a has a tree-shaped cross-section, and the surface of the fixing element 40a is partially hollow. In addition, a plurality of positioning ribs 102a disposed at the fixing element 40a are clamped and fixed onto an external surface of the heat dissipating plate 10a for positioning the fixing elements 40a.

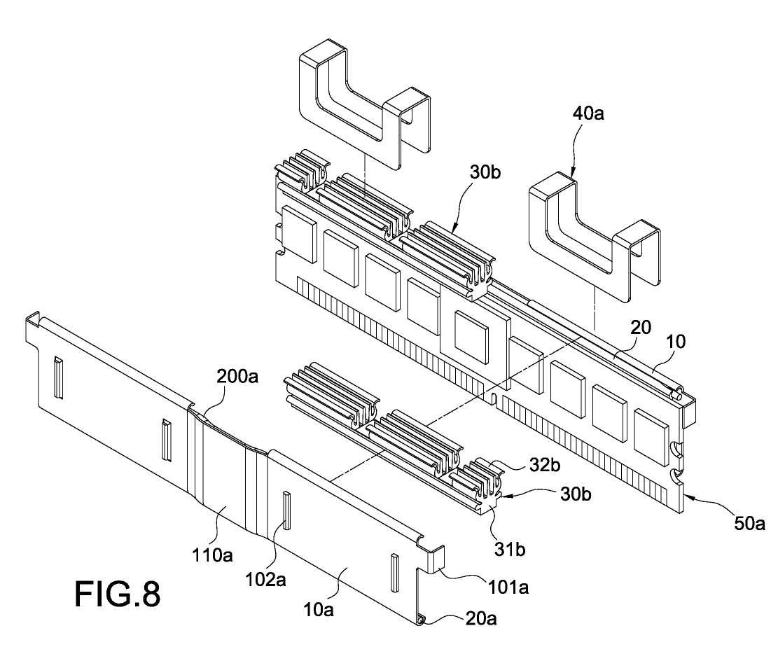

With reference to FIG. 8 for a fourth preferred embodiment of the present invention, this preferred embodiment is substantially the same as the third preferred embodiment, and the difference resides on the shape of the combined heat dissipating body 30b, and the heat dissipating body 30b includes a base 31b and a heat dissipating fin 32b formed on the base 31b, and the heat dissipating fin 32b of this preferred embodiment has a flame-shaped cross-section for expediting the heat dissipation.

The memory heat dissipating structure of the present invention is clamped with a corresponding surface of the memory module 50, since a portion of the uniform temperature plate 20 is attached to a straight section 311 of the heat dissipating body 30, and thus the heat is dissipated directly from the uniform temperature plate 20 to the heat dissipating body 30 to enhance the heat dissipating efficiency of the heat dissipating body 30 with respect to the memory module 50, without the need of conducting the heat indirectly to the uniform temperature plate as required in the heat dissipating plate of the convectional memory heat dissipating structure, and then the heat is conducted by the heat dissipating plate to the heat dissipating body and dissipated to the outside. Since the uniform temperature plate 20 is installed at the memory heat dissipating structure and combined the heat dissipating body 30 having the heat dissipating fin, the heat produced by the memory module 50 can be removed. With the thin and light structure of the uniform temperature plate 20, the present invention fits an application in a computer with limited internal space. The heat dissipating body 30 includes an insert slot 312 for inserting the second bent section 12 of the heat dissipating plate 10, and allowing users to replace various types of heat dissipating bodies, so as to enhance the convenience and practicability of the present invention.

While the invention has been described by means of specific embodiments, numerous modifications and variations could be made thereto by those skilled in the art without departing from the scope and spirit of the invention set forth in the claims.

What is claimed is:

1. A memory heat dissipating structure, clamped and fixed to a corresponding surface of a memory module, and the heat dissipating structure comprising:
two heat dissipating plates;
at least one uniform temperature plate, having a first surface and a second surface corresponding to each other, and the first surface being attached onto an internal side of the heat dissipating plate, and the second surface being attached onto the memory module;
at least one heat dissipating body, installed on the memory module, and clamped between the two heat dissipating plates, and the heat dissipating body including a base and a plurality of heat dissipating fins extended from the base, and the base forming a straight section attached onto the second surface of the uniform temperature plate; and
at least one fixing element, clamped and fixed to the two heat dissipating plates.

2. The memory heat dissipating structure of claim 1, wherein the heat dissipating plate includes a first bent section inwardly bent from a side of the heat dissipating plate, and the first bent section is provided for installing the uniform temperature plate.

3. The memory heat dissipating structure of claim 2, wherein the heat dissipating plate includes a second bent section inwardly bent from another side of the heat dissipating plate, and the base of the heat dissipating body forms an insert slot for inserting the second bent section.

4. The memory heat dissipating structure of claim 1, wherein the straight section is formed on both left and right sides of the base.

5. The memory heat dissipating structure of claim 1, further comprising a thermal conducting medium coated between the second surface of the uniform temperature plate and the memory module.

6. The memory heat dissipating structure of claim 1, wherein the heat dissipating fin has a substantially tree-shaped cross-section.

7. The memory heat dissipating structure of claim 1, wherein the heat dissipating fin has a substantially flame-shaped cross-section.

8. The memory heat dissipating structure of claim 1, wherein the fixing element includes two elastic clamping plates corresponding to each other and coupled to a connecting plate of the two clamping plates.

9. The memory heat dissipating structure of claim 1, wherein the fixing element has a substantially U-shaped cross-section.

10. A memory device having a heat dissipating structure, comprising:
a memory module;
two heat dissipating plates;
at least one uniform temperature plate, having a first surface and a second surface corresponding to each other, and the first surface being attached onto an internal side of the heat dissipating plate, and the second surface being attached to the memory module;
at least one heat dissipating body, installed on the memory module, and clamped between the two heat dissipating plates, and the heat dissipating body including a base and a plurality of heat dissipating fins extended from the base, and the base forming a straight section attached onto the second surface of the uniform temperature plate; and
at least one fixing element, clamped and fixed to the two heat dissipating plates.

11. The memory device having a heat dissipating structure of claim 10, wherein the heat dissipating plate includes a first bent section inwardly bent from a side of the heat dissipating plate, and the first bent section is provided for installing the uniform temperature plate.

12. The memory device having a heat dissipating structure of claim 11, wherein the heat dissipating plate includes a second bent section inwardly bent from another side of the heat dissipating plate, and the base of the heat dissipating body forms an insert slot for inserting the second bent section.

13. The memory device having a heat dissipating structure of claim 10, wherein the straight section is formed on both left and right sides of the base.

14. The memory device having a heat dissipating structure of claim 10, further comprising a thermal conducting medium coated between the second surface of the uniform temperature plate and the memory module.

15. The memory device having a heat dissipating structure of claim 10, wherein the heat dissipating fin has a substantially tree-shaped cross-section.

16. The memory device having a heat dissipating structure of claim 10, wherein the heat dissipating fin has a substantially flame-shaped cross-section.

17. The memory device having a heat dissipating structure of claim 10, wherein the fixing element includes two elastic clamping plates corresponding to each other, and coupled to a connecting plate of the two clamping plates.

18. The memory device having a heat dissipating structure of claim 10, wherein the fixing element has a substantially U-shaped cross-section.
